(19) United States
(12) Patent Application Publication
(10) Pub. No.: US 2013/0012030 A1
(43) Pub. Date: Jan. 10, 2013

(54) METHOD AND APPARATUS FOR REMOTE PLASMA SOURCE ASSISTED SILICON-CONTAINING FILM DEPOSITION

(75) Inventors: Annamalai Lakshmanan, Freemont, CA (US); Jianshe Tang, San Jose, CA (US); Dustin W. Ho, Fremont, CA (US); Francimar C. Schmitt, Santa Clara, CA (US); Alan Tso, San Jose, CA (US); Tom K. Cho, Los Altos, CA (US); Brian Sy-Yuan Shieh, Palo Alto, CA (US); Hari K. Ponnekanti, San Jose, CA (US); Chris Eberspacher, Palo Alto, CA (US); Zheng Yuan, Cupertino, CA (US)

(73) Assignee: Applied Materials, Inc., Santa Clara, CA (US)

(21) Appl. No.: 13/634,526

(22) PCT Filed: Mar. 17, 2010
(86) PCT No.: PCT/CN2010/000325

§ 371 Date: Sep. 12, 2012

(51) Int. Cl. H01L 21/31

(52) U.S. Cl. 438/758; 118/723 R; 257/E21.24

(57) ABSTRACT

An apparatus and methods for depositing amorphous and microcrystalline silicon films during the formation of solar cells are provided. In one embodiment, a method and apparatus is provided for generating and introducing hydrogen radicals directly into a processing region of a processing chamber for reaction with a silicon-containing precursor for film deposition on a substrate. In one embodiment, the hydrogen radicals are generated by a remote plasma source and directly introduced into the processing region via a line of sight path to minimize the loss of energy by the hydrogen radicals prior to reaching the processing region.

### BACKGROUND OF THE INVENTION

1. Field of the Invention

Embodiments of the invention relate to an apparatus and method for forming solar cells. More particularly, embodiments of the present invention relate to an apparatus and method for forming amorphous and microcrystalline silicon layers utilized in solar cell applications.

2. Description of the Related Art

Photovoltaic (PV) devices or solar cells are devices which convert sunlight into direct current (DC) electrical power. Typical thin film PV devices, or thin film solar cells, have one or more p-i-n junctions. Each p-i-n junction comprises a p-type layer, an intrinsic type layer, and an n-type layer. When the p-i-n junction of the solar cell is exposed to sunlight (consisting of energy from photons), the sunlight is converted to electricity through the PV effect. Solar cells may be tiled into larger solar arrays.

Typically, a thin film solar cell includes active regions, or photoelectric conversion units, and a transparent conductive oxide (TCO) film disposed as a front electrode and/or as a back electrode. The photoelectric conversion unit includes a p-type silicon layer, an n-type silicon layer, and an intrinsic type (i-type) silicon layer sandwiched between the p-type and n-type silicon layers. Several types of silicon films including microcrystalline silicon film (μc-Si), amorphous silicon film (a-Si), polycrystalline silicon film (poly-Si), and the like may be utilized to form the p-type, n-type, and/or i-type layers of the photoelectric conversion unit. The backside electrode may contain one or more conductive layers.

Both amorphous and microcrystalline silicon films are currently being used to form solar cells. However, problems exist in current production equipment and methods used in the deposition of these films. For example, in conventional thermal chemical vapor deposition and plasma enhanced chemical vapor deposition (PECVD) processes, the low energy gas phase combination of silicon and hydrogen leads to the formation of polymerized silicon and hydrogen structures, which can lead to particle generation, inefficient film deposition, and physically and electrically inferior and unstable deposited films.

Therefore, there is a need for an improved apparatus and method for depositing amorphous and microcrystalline silicon films.

### SUMMARY OF THE INVENTION

In one embodiment of the present invention, a method for depositing a silicon-containing film comprises generating hydrogen radicals remotely from a processing chamber, introducing a flow of the hydrogen radicals into a processing region of the processing chamber, wherein a substrate is positioned in the processing region, introducing a flow of silicon-containing gas into the processing region of the processing chamber, and depositing the silicon film on the substrate. The remotely generated hydrogen radicals are not mixed with the silicon-containing gas prior to reaching the processing region.

In another embodiment, a method for depositing a silicon-containing film comprises establishing a flow of argon gas into a remote plasma source, igniting a plasma within the remote plasma source, establishing a flow of hydrogen gas into the remote plasma source such that a flow of hydrogen radicals is established, delivering the flow of hydrogen radicals into a processing region of a processing chamber, wherein a substrate is positioned in the processing region, generating a flow of silicon-containing gas into the processing region of the processing chamber, and depositing the silicon film on the substrate. The hydrogen radicals are not mixed with the silicon-containing gas prior to reaching the processing region of the processing chamber.

In yet another embodiment of the present invention, an apparatus for depositing a silicon-containing film comprises a processing chamber having a plurality of walls, a showerhead, and a substrate support that define a processing region within the processing chamber, a silicon-containing gas source coupled to the processing region through a first plurality of gas passages disposed through the showerhead, a remote plasma source coupled to a hydrogen gas source and configured to generate a plurality of hydrogen radicals therein, line of sight tubing coupling the remote plasma source to the processing chamber, wherein the line of sight tubing comprises an inert material, and a feed tube coupling the line of sight tubing to the processing region such that hydrogen radicals delivered by the feed tube do not mix with a silicon-containing gas prior to entering the processing region.

### BRIEF DESCRIPTION OF THE DRAWINGS

So that the manner in which the above-recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a simplified schematic diagram of a single junction amorphous silicon solar cell that may be formed, in part, using methods and apparatus according to embodiments of the present invention.

FIG. 2 is a schematic diagram of another embodiment of a multi-junction solar cell that may be formed, in part, using methods and apparatus according to embodiments of the present invention.

FIG. 3 is a schematic, cross-sectional view of a processing chamber for depositing amorphous and microcrystalline films according to one embodiment of the present invention.

FIG. 4 is a schematic, cross-sectional view of a showerhead for separately delivering hydrogen radicals from a remote plasma source and a process gas from a processing gas source into a processing region of a processing chamber according to another embodiment.

FIG. 5 is a schematic depiction of a process flow for hydrogen radical generation according to one embodiment of the present invention.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments of the present invention generally provide improved apparatus and methods for depositing amorphous and microcrystalline silicon films during the formation of solar cells. In one embodiment, a method and apparatus is provided for generating and introducing hydrogen radicals directly into a processing region of a processing chamber for reaction with a silicon-containing precursor for film deposition on a substrate. In one embodiment, the hydrogen radicals are generated by a remote plasma source and directly introduced into the processing region via a line of sight path to minimize the loss of energy by the hydrogen radicals prior to reaching the processing region. The line of sight path may include tubing formed from a non-reactive material, such as a dielectric or ceramic material. In some configurations, it is desirable to heat the tubing to reduce the possible transfer of energy to the tubing and prevent adsorption of the hydrogen radicals onto the surface of the tubing prior to introduction into the processing region.

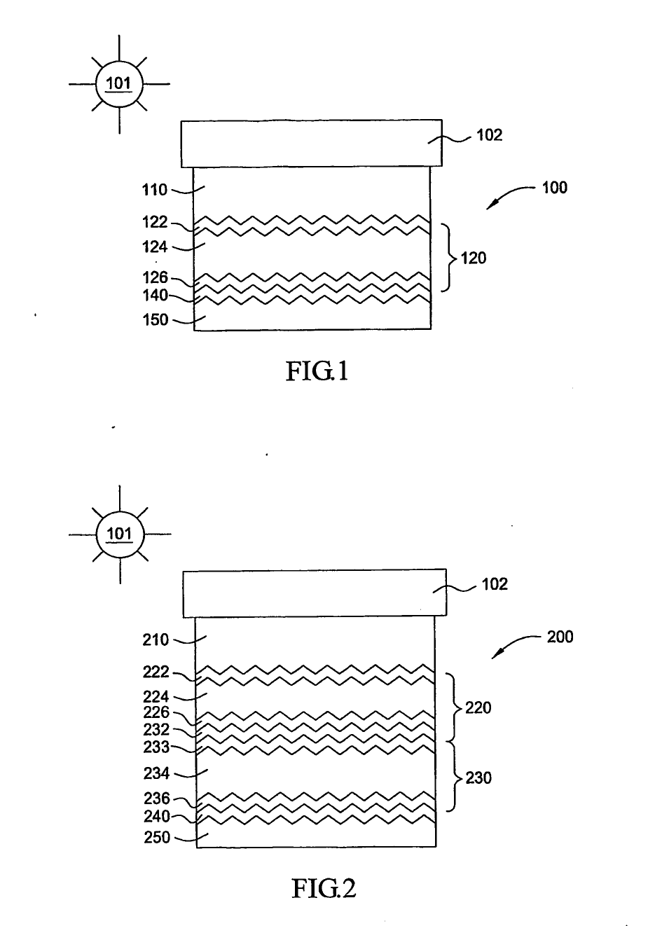

FIG. 1 is a simplified schematic diagram of a single junction amorphous silicon solar cell 100 that may be formed, in part, using methods and apparatus according to embodiments of the present invention. The single junction solar cell 100 is oriented toward a light source or solar radiation 101. The solar cell 100 generally comprises a substrate 102, such as a glass substrate, polymer substrate, metal substrate, or other suitable substrate, with thin films formed thereover. In one embodiment, the substrate 102 is a glass substrate that is about 2200 mm×2600 mm×3 mm in size. The solar cell 100 further comprises a first transparent conducting oxide (TCO) layer 110 (e.g., zinc oxide (ZnO), tin oxide (SnO)) formed over the substrate 102, a first p-i-n junction 120 formed over the first TCO layer 110, a second TCO layer 140 formed over the first p-i-n junction 120, and a back contact layer 150 formed over the second TCO layer 140.

In one configuration, the first p-i-n junction 120 may comprise a p-type amorphous silicon layer 122, an intrinsic type amorphous silicon layer 124 formed over the p-type amorphous silicon layer 122, and an n-type amorphous silicon layer 126 formed over the intrinsic type amorphous silicon layer 124. In one example, the p-type amorphous silicon layer 122 may be formed to a thickness between about 60 Å and about 300 Å, the intrinsic type amorphous silicon layer 124 may be formed to a thickness between about 1,500 Å and about 3,500 Å, and the n-type amorphous semiconductor layer 126 may be formed to a thickness between about 100 Å and about 500 Å. The back contact layer 150 may include, but is not limited to, aluminum (Al), silver (Ag), titanium (Ti), chromium (Cr), gold (Au), copper (Cu), platinum (Pt), alloys thereof, or combinations thereof.

FIG. 2 is a schematic diagram of an embodiment of a solar cell 200, which is a multi-junction solar cell that is oriented toward the light or solar radiation 101. The solar cell 200 comprises a substrate 102, such as a glass substrate, polymer substrate, metal substrate, or other suitable substrate, with thin films formed thereover. The solar cell 200 may further comprise a first transparent conducting oxide (TCO) layer 210 formed over the substrate 102, a first p-i-n junction 220 formed over the first TCO layer 210, a second p-i-n junction 230 formed over the first p-i-n junction 220, a second TCO layer 240 formed over the second p-i-n junction 230, and a back contact layer 250 formed over the second TCO layer 240.

The first p-i-n junction 220 may comprise a p-type amorphous silicon layer 222, an intrinsic type amorphous silicon layer 224 formed over the p-type amorphous silicon layer 222, and an n-type microcrystalline silicon layer 226 formed over the intrinsic type amorphous silicon layer 224. In one example, the p-type amorphous silicon layer 222 may be formed to a thickness between about 60 Å and about 300 Å, the intrinsic type amorphous silicon layer 224 may be formed to a thickness between about 1,500 Å and about 3,500 Å, and the n-type microcrystalline semiconductor layer 226 may be formed to a thickness between about 100 Å and about 400 Å.

The second p-i-n junction 230 may comprise a p-type microcrystalline silicon layer 232, an intrinsic type microcrystalline silicon layer 234 formed over the p-type microcrystalline silicon layer 232, and an n-type amorphous silicon layer 236 formed over the intrinsic type microcrystalline silicon layer 234. In one embodiment, prior to deposition of the intrinsic type microcrystalline silicon layer 234, an intrinsic microcrystalline silicon seed layer 233 may be formed over the p-type microcrystalline silicon layer 232. In one example, the p-type microcrystalline silicon layer 232 may be formed to a thickness between about 100 Å and about 400 Å, the intrinsic type microcrystalline silicon layer 234 may be formed to a thickness between about 10,000 Å and about 30,000 Å, and the n-type amorphous silicon layer 236 may be formed to a thickness between about 100 Å and about 500 Å. In one embodiment, the intrinsic microcrystalline silicon seed layer 233 may be formed to a thickness between about 50 Å and about 500 Å. The back contact layer 250 may include, but is not limited to, aluminum (Al), silver (Ag), titanium (Ti), chromium (Cr), gold (Au), copper (Cu), platinum (Pt), alloys thereof, or combinations thereof.

Current methods of depositing the various amorphous and microcrystalline silicon films to form the solar cell 100, 200 include introducing a mixture of hydrogen-based gas, such as hydrogen gas (H₂), and silicon-based gas, such as silane (SiH₄), into a processing region of a plasma enhanced chemical vapor deposition (PECVD) processing chamber, exciting the gas mixture into a plasma, and depositing the desired film on the substrate 102. During this process, two types of bonds are formed and deposited onto the substrate, namely Si—H bonds and Si—H₂ bonds. It has been found that the H₂ bonds are undesirable because they form particles or defects in the deposited film, resulting in less efficient, lower quality bonds and film deposition. Therefore, it is desirable to increase Si—H bond formation and reduce Si—H₂ bond formation during the deposition process. Additionally, it is desirable to reduce polymerization of silicon into long chain polymers, which also results in defects formed in and instability of the deposited films. Embodiments of the present invention accomplish these results by directly introducing hydrogen radicals into the processing region of the processing chamber separately from the silicon-based gas, such that the hydrogen radicals combine with the silicon-based gas to produce significantly more Si—H bonds during the deposition process than current methods and apparatus. It is believed that the use of conventional plasma processing techniques, which use a single capacitively or inductively coupled plasma source to deliver energy to a combination of processing gases (e.g., silane and hydrogen gas) disposed in a processing region of a processing chamber, are not effective or efficient in coupling the RF power to the hydrogen atoms in the process gas mixture to create a desirable percentage of reactive hydrogen radicals to form the more desirable Si—H bonds versus the Si—H₂ bonds in the deposited silicon layer. In one example, it is believed that a single capacitively coupled plasma source, such as a RF driven showerhead disposed over a substrate, is only able to convert about 10-20% of hydrogen atoms in a silane and hydrogen gas mixture into hydrogen radicals. Therefore, by use of the combination of a capacitively or inductively coupled plasma source that delivers energy to a process gas mixture comprising hydrogen radicals delivered from a remote plasma source and a silicon-containing gas delivered from a separate gas source, the deposited film quality and electrical characteristics of the deposited film can be greatly improved. For instance, embodiments of the present invention yield hydrogen radical delivery to the process chamber on the order of 30-70% as opposed to the prior art 10-20%. It should be noted that the term “hydrogen radical” as used herein denotes a single, highly reactive, neutral hydrogen atom.

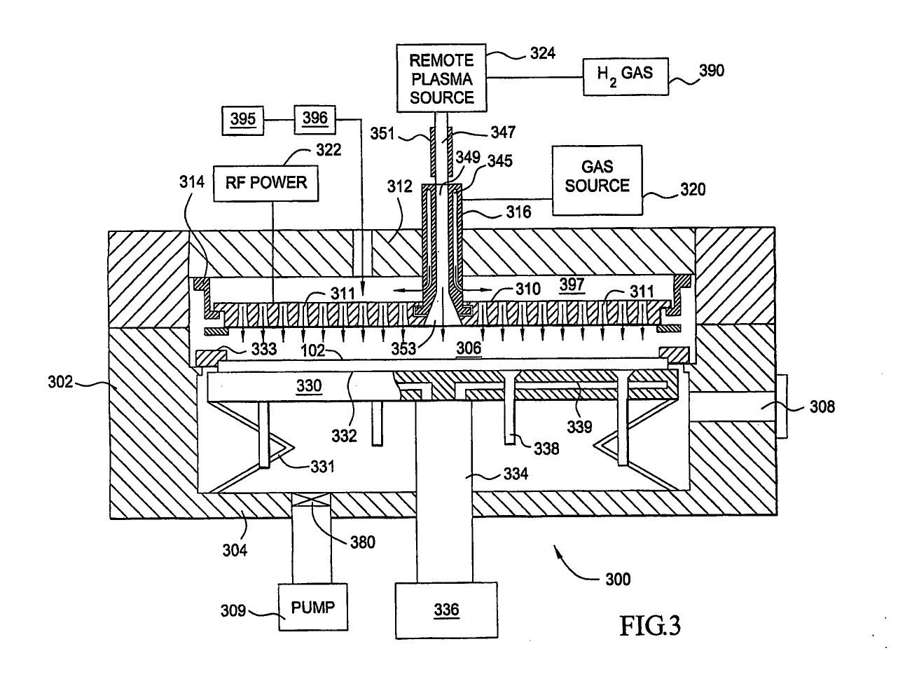

FIG. 3 is a schematic, cross-sectional view of a processing chamber 300 for depositing amorphous and microcrystalline films according to one embodiment of the present invention. In one embodiment, the chamber 300 includes walls 302, a bottom 304, a showerhead 310, and a substrate support 330, which cumulatively define a processing region 306. The processing region 306 is accessed through a valve 308, such that a substrate 102 may be transferred into and out of the chamber 300. The substrate support 330 includes a substrate receiving surface 332 for supporting the substrate 102 and stem 334 coupled to a lift system 336 configured to raise and lower the substrate support 330. A shadow frame 333 may be optionally placed over a periphery of the substrate 102. Lift pins 338 are moveably disposed through the substrate support 330 to move the substrate 102 to and from the substrate receiving surface 332. The substrate support 330 may also include heating and/or cooling elements 330 to maintain the substrate support 330 at a desired temperature. The substrate support 330 may also include grounding straps 331 to provide RF grounding at the periphery of the substrate support 330.

The showerhead 310 is coupled to a backing plate 312 at its periphery by a suspension 314. The showerhead 310 may also be coupled to the backing plate by one or more center supports 316 to help prevent sag and/or control the straightness/curvature of the showerhead 310. A gas source 320 is configured to supply a processing gas, such as a silicon-containing gas, through a gas feed tube 345. In one embodiment, the gas feed tube 345 is an annular tube configured to feed the processing gas to the processing region 306 through a plurality of gas passages 311 in the showerhead 310.

A hydrogen gas source 390 is fluidly coupled to a remote plasma source 324, such as an inductively coupled remote plasma source. The remote plasma source 324 is also fluidly coupled to the processing region 306 through line of sight tubing 347 and a central feed tube 349. The line of sight tubing 347 fluidly couples the remote plasma source 324 to the central feed tube 349. The term “line of sight” used herein is meant to convey a short distance between the remote plasma source 324 and the processing chamber 300 so as to minimize the possibility of hydrogen radical recombination or adsorption onto the surface of the tubing. In one embodiment, the line of sight tubing 347 provides a direct path for the hydrogen radicals without any sharp bends therein. In one embodiment, the line of sight tubing 347 provides a direct path for the hydrogen radicals without any bends therein. The line of sight tubing 347 comprises tubing made of an inert material, such as sapphire, quartz, or other ceramic material, to prevent adsorption and/or recombination of the hydrogen radicals provided by the remote plasma source 324. Additionally, a heater jacket 351 may be provided to further prevent adsorption and/or recombination of the hydrogen radicals provided by the remote plasma source 324 prior to their delivery into the processing region 306. The line of sight tubing 347 and the central feed tube 349 are configured to provide a direct, short path for hydrogen radicals generated in the remote plasma source 324 into the processing region 306. In one embodiment, the central feed tube 349 is configured to directly feed hydrogen radicals generated in the remote plasma source 324 through a central opening 353 in the showerhead 310 into the processing region 306, as shown in FIG. 3.

In one embodiment, the processing chamber 300 also includes a cleaning gas remote plasma source 395 that is fluidly coupled to a gas plenum 397, located behind the showerhead 310, and further coupled to the processing region 306 through the gas passages 311 formed in the showerhead 310. The cleaning gas remote plasma source 395 is coupled to a cleaning gas source 396 that is able to deliver a cleaning gas to the cleaning gas remote plasma source 395 so that energetic cleaning gases can be formed to clean the surfaces of the showerhead 310 and other chamber components between deposition processes. Typical cleaning gases include halogen-containing gases, such as NF₃, F₂, Cl₂, or other gases which are used to remove portions of deposited material formed on chamber components during prior deposition processes. One will note that while the positioning of an outlet 398 of the cleaning gas remote plasma source 395, as illustrated in FIG. 3, is generally required to assure that the surfaces of the showerhead 310 and chamber components can be efficiently cleaned during the chamber clean processes, it is generally not a desirable location to deliver hydrogen radicals for use during the deposition processes according to embodiments of the present invention. The location of the outlet 398, as illustrated in FIG. 3, is generally not desirable for introducing hydrogen radicals into the processing region 306 because the formation of gas phase particles in the gas plenum 397 created by the interaction of the formed hydrogen radicals and the precursor gas(es) delivered from the processing gas source 320 is likely, which would provide undesirable deposition behind and within the showerhead 310.

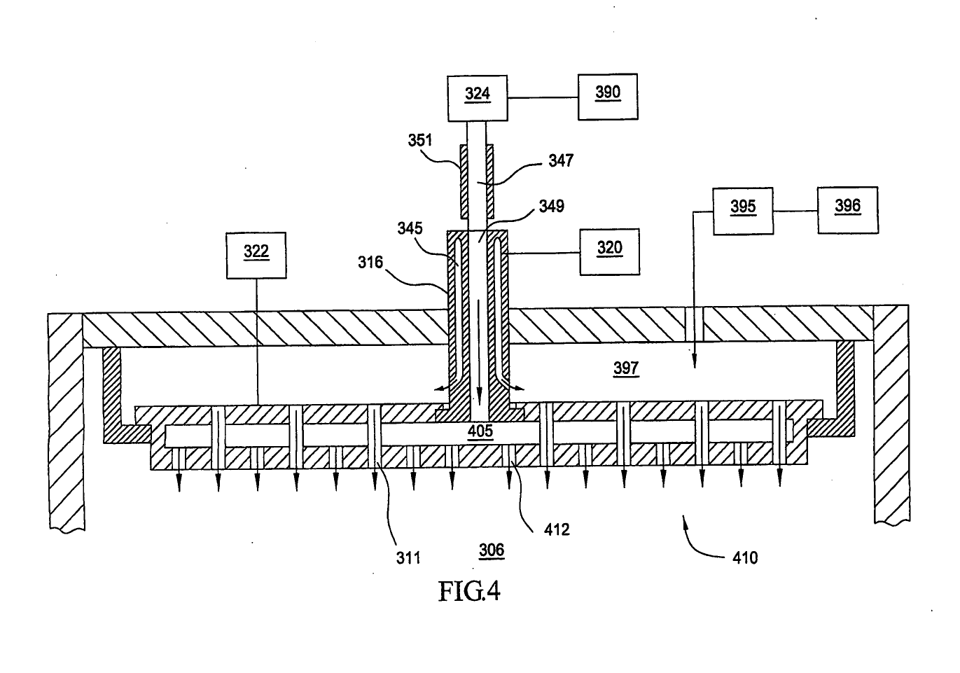

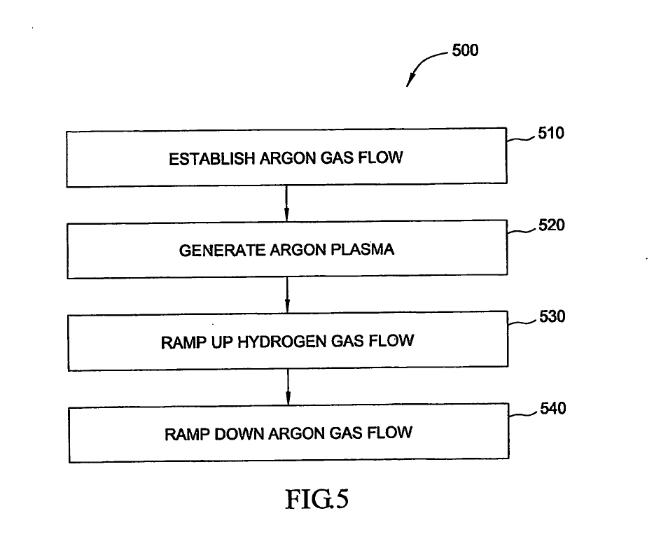

FIG. 4 is a schematic, cross-sectional view of a showerhead 410 for separately delivering hydrogen radicals from the remote plasma source 324 and a process gas from the processing gas source 320 into the processing region 306 of the processing chamber 300 according to another embodiment. In this embodiment, the central feed tube 349 is fluidly coupled to an interior region 405 within the showerhead 410. The interior region 405 is, in turn, fluidly coupled to a plurality of passages 412 fluidly connecting the interior region 405 of the showerhead 410 to the processing region 306 of the processing chamber 300. In this configuration, the hydrogen radicals are delivered from the remote plasma source 324, through the line of sight tubing 347 and the central feed tube 349 into the interior region 405 of the showerhead 410. From there, the hydrogen radicals are evenly distributed into the processing region 306 through the plurality of passages 412. Simultaneously, a processing gas, such as silane, is delivered from the gas source 320, through the gas feed tube 345, and through the plurality of gas passages 311 in the showerhead 410 into the processing region 306.

An RF power source 322 is coupled to the backing plate 312 and/or to the showerhead 310, 410 to provide a RF power to the showerhead 310, 410 so that an electric field is created between the showerhead 310, 410 and the substrate support 330 or chamber walls 302. Thus, a capacitvely coupled plasma is generated in the processing region 306 for depositing a film on the substrate 102. A vacuum pump 309 is also coupled to the processing chamber 300 through a throttle valve 380 to control the processing region 306 at a desired pressure.

Regardless of the specific embodiment, the gas source 320, remote plasma source 324, and the showerhead 310, 410 are configured such that hydrogen radicals generated in the remote plasma source 324 are introduced to the processing gas only within the processing region 306 in order to prevent undesirable mixing and undesirable deposition in other regions of the processing chamber 300. Further, the hydrogen radicals are delivered directly into the processing region 306 to minimize recombination or energy loss by the hydrogen atoms prior to mixing with the processing gas(es) disposed in the processing region 306. Thus, undesirable the undesirable Si—H₂ bonds are minimized and the desirable Si—H bonds are maximized to provide better more efficient silicon film deposition.

In one embodiment, hydrogen radicals are generated within one or more remote plasma sources, such as the remote plasma source 324 depicted in FIGS. 3 and 4. In one embodiment, the hydrogen radicals are generated from a single remote plasma source coupled directly to the processing region 306. In another embodiment, the hydrogen radicals are generated from a plurality of remote plasma sources that are each coupled directly to the processing region 306. In one embodiment, a plurality of the remote plasma sources 324 are evenly spaced across the showerhead 310, 410 so that by controlling the gas flow rate and remote plasma source power from each of the evenly spaced remote plasma sources 324, a uniform flow of hydrogen radicals can be delivered into the processing region 306. In another embodiment, a plurality of remote plasma sources 324 are spaced in a desirable pattern across the showerhead 310 and controlled in a desirable way to provide a non-uniform flow of hydrogen radicals into the processing region 306 to improve some aspect of the deposition process results. In one embodiment, the one or more remote plasma sources may be rated for power output from about 10 kW to about 40 kW or greater, depending on the size of the substrate 102 being processed in the processing chamber 300. In one embodiment, an RF power of between about 14 W/cm² and about 18 W/cm² is used.

FIG. 5 illustrates an example of a process sequence 500 used to begin the formation of hydrogen radicals in the remote plasma source 324, for example, at the start of a deposition process. In one embodiment, an argon gas flow rate to the remote plasma source 324 is first established at box 510. In one embodiment, the argon gas flow rate is provided between about 40 sccm/L and about 750 sccm/L. In box 520, the argon is ignited into a plasma within the remote plasma source and the throttle valve 380 in the processing chamber 300 is opened. Next, hydrogen gas is supplied to the remote plasma source 324 at a flow rate between about 0.4 sccm/Us and about 40 sccm/Us in box 530. The flow rate of the hydrogen gas may be continually ramped up to a steady state flow of between about 40 sccm/L and about 205 sccm/L. In box 540, the flow of argon is ramped down at a flow rate from about 0.4 sccm/L/s to about 17 sccm/L/s until the flow of argon reaches a desirable point such that a steady flow of hydrogen radicals is present at the exit of the remote plasma source 324. In one embodiment, the flow of argon is ramped down to zero, such as when used at processing chamber pressures of from about 0.1 Torr to about 1 Torr. In another embodiment, the flow of argon is continued at a low rate only for maintaining the generation of hydrogen radicals, such as when used at processing chamber pressures above about 1 Torr.

In one embodiment, it is desirable to adjust the pressure, gas flow rates, and/or ratio of gases, such as carrier gases (e.g., argon) to hydrogen ratio, delivered to the plasma generation region in the remote plasma source 324 to prevent the plasma generated therein from extinguishing, when the composition and/or pressure in the processing region 306 of the processing chamber 300 is varied during the deposition processes performed on the substrate 102.

An example of the deposition methods used to form the amorphous and microcrystalline silicon layers contained in the solar cells 100 and 200 of FIGS. 1 and 2 using the processing chamber 300 of FIGS. 3 and 4 according to the present invention is provided below. A substrate having a surface area of 10,000 cm² or more, preferably 40,000 cm² or more, and more preferably 55,000 cm² or more is provided to the processing chamber 300.

In one embodiment, the heating and/or cooling elements 339 are set to provide a substrate support temperature during deposition of about 400 degrees Celsius or less, preferably between about 150 degrees Celsius and about 400 degrees Celsius. The spacing during deposition between the top surface of the substrate 102 disposed on the substrate receiving surface 332 and the showerhead 310, 410 may be between about 200 mil and about 1,000 mil.

For deposition of the silicon films, a silicon-based gas is generally provided by the gas source 320. Suitable silicon based gases include, but are not limited to silane (SiH₄), disilane (Si₂H₆), silicon tetrafluoride (SiF₄), silicon tetrachloride (SiCl₄), dichlorosilane (SiH₂Cl₂), and combinations thereof. The p-type dopants of the p-type layers may each comprise a group III element, such as boron or aluminum. Examples of boron-containing sources include trimethylboron (TMB), diborane (B₂H₆), and similar compounds. The n-type dopants of the n-type silicon layers may each comprise a group V element, such as phosphorus, arsenic, or antimony. Examples of phosphorus-containing sources include phosphine and similar compounds. The dopants are typically provided with a carrier gas, such as hydrogen, argon, helium, and other suitable compounds.

The following illustrates an example of a processing sequence that may be used to form a tandem cell, such as the solar cell 200 illustrated in FIG. 2, in one or more processing chambers 300, shown in FIGS. 3 and 4, according to embodiments of the present invention. In one embodiment, a substrate 102 having a front TCO layer 110 deposited thereon is received into one processing chamber 300. A p-type amorphous silicon layer 122 may be formed on the substrate 102 by providing silane gas at a flow rate between about 1 sccm/L and about 10 sccm/L from the gas source 320, through the gas feed tube 345, and through the plurality of gas passages 311 in the showerhead 310, 410 into the processing region 306. Simultaneously, hydrogen radicals, generated in the remote plasma source 324 according to the description provided above with respect to FIG. 5, are provided through the line of sight tubing 347, the central feed tube 349, and the showerhead 310, 410 into the processing region 306. Trimethylboron may be provided with the silane at a flow rate between about 0.005 sccm/L and bout 0.05 sccm/L. Methane may also be provided at a flow rate between about 1 sccm/L and about 15 sccm/L. An RF power between about 15 mW/cm² and about 200 mW/cm² may be provided to the showerhead 310, 410 to form a plasma in the processing region 306 (FIG. 3) over the surface of the substrate 102. The formed plasma over the substrate 102 comprises the silane gas delivered through the showerhead 310, 410 and the hydrogen radicals delivered from the remote plasma source 324. The pressure of the processing chamber 300 may be maintained between about 0.1 Torr and about 20 Torr, preferably between about 1 Torr and about 4 Torr.

Next, the substrate 102 may be transferred into another processing chamber, which is similarly configured to the processing chamber 300, for deposition of an intrinsic type amorphous silicon layer 124 over the p-type amorphous silicon layer 122. In one embodiment, silane gas is provided at a flow rate between about 0.5 sccm/L and about 7 sccm/L from the gas source 320, through the gas feed tube 345, and through the plurality of gas passages 311 in the showerhead 310, 410 into the processing region 306. Simultaneously, hydrogen radicals, generated in the remote plasma source 324 according to the description provided above with respect to FIG. 5, are provided through the line of sight tubing 347, the central feed tube 349, and the showerhead 310, 410 into the processing region 306. An RF power between about 15 mW/cm² and about 250 mW/cm² may be provided to the showerhead 310, 410 to deliver energy to the silane and the hydrogen radical mixture in the processing region 306. The pressure of the processing chamber 300 may be between about 0.5 Torr and about 5 Torr.

Next, while the substrate 102 is still in the processing chamber 300, an n-type microcrystalline silicon layer 126 is deposited on the intrinsic type amorphous silicon layer 124. In one embodiment, silane gas is provided at a flow rate between about 0.1 sccm/L and about 0.8 sccm/L, such as about 0.35 sccm/L from the gas source 320, through the gas feed tube 345, and through the plurality of gas passages 311 in the showerhead 310, 410 into the processing region 306. Simultaneously, hydrogen radicals, generated in the remote plasma source 324 according to the description provided above with respect to FIG. 5, are provided through the line of sight tubing 347, the central feed tube 349, and the showerhead 310, 410 into the processing region 306. Phosphine may be provided with the silane at a flow rate between about 0.0005 sccm/L and about 0.06 sccm/L. An RF power between about 100 mW/cm² and about 900 mW/cm² may be provided to the showerhead 310, 410 to deliver energy to the silane and the hydrogen radical mixture in the processing region 306. The pressure of the processing chamber 300 may be between about 1 Torr and about 100 Torr, preferably between about 3 Torr and about 20 Torr.

Next, the substrate 102 is moved to another processing chamber 300 for depositing a p-type microcrystalline silicon layer 132 over the n-type microcrystalline silicon layer 126. In one embodiment, silane gas is provided at a flow rate between about 0.1 sccm/L and about 0.8 sccm/L from the gas source 320, through the gas feed tube 345, and through the plurality of gas passages 311 in the showerhead 310, 410 into the processing region 306. Simultaneously, hydrogen radicals, generated in the remote plasma source 324 according to the description provided above with respect to FIG. 5, are provided through the line of sight tubing 347, the central feed tube 349, and the showerhead 310, 410 into the processing region 306. Trimethylboron may be provided along with the silane at a flow rate between about 0.0002 sccm/L and about 0.0016 sccm/L. An RF power between about 50 mW/cm² and about 700 mW/cm² may be provided to the showerhead 310, 410 to deliver energy to the silane and the hydrogen radical mixture in the processing region 306. The pressure of the processing chamber 300 may be between about 1 Torr and about 100 torr, preferably between about 3 Torr and about 20 Torr.

Next, the substrate 102 is transferred into another processing chamber 300 for deposition of the intrinsic type microcrystalline silicon seed layer 133 over the p-type microcrystalline silicon layer 132. In one embodiment, silane gas is gradually ramped up from a zero point to a second set point, such as between about 2.8 sccm/L and about 5.6 sccm/L over a time period from about 20 seconds to about 300 seconds, such as between about 40 seconds and about 240 seconds. The ramped up silane flow is provided from the gas source 320, through the gas feed tube 345, and through the plurality of gas passages 311 in the showerhead 310, 410 into the processing region 306. Simultaneously, hydrogen radicals, generated in the remote plasma source 324 according to the description provided above with respect to FIG. 5, are provided through the line of sight tubing 347, the central feed tube 349, and the showerhead 310, 410 into the processing region 306. An RF power may also be ramped up similarly to the silane flow from about 0 Watts to about 2 Watts/cm² to deliver energy to the silane and the hydrogen radical mixture in the processing region 306. The pressure of the processing chamber 300 may be between about 1 Tor and about 12 Torr.

It is believed that the gradual ramp-up of the silane gas flow in the intrinsic type microcrystalline silicon seed layer 133 formation assists silicon atoms in uniformly adhering and distributing on the surface of the substrate 102, thereby forming the intrinsic type microcrystalline silicon seed layer 133 with desirable film properties. Uniform adherence of the silicon atoms on the surface of the substrate 102 provides good nucleation sites for subsequent atoms to nucleate thereon. Uniform nucleation sites formed on the substrate 102 promote crystallinity of films subsequently formed thereon. Therefore, the gradual ramp-up of the silane flow into the processing region 306 allows the dissociated silicon atoms to have sufficient time to be gradually absorbed on the surface of the substrate 102, thereby providing a surface having an even distribution of silicon atoms that provides nucleation sites, which promote improved crystallinity of subsequently deposited layers.

Next, an intrinsic type microcrystalline silicon layer 134 is deposited over the intrinsic type microcrystalline silicon seed layer 133 in the processing chamber 300. Silane gas may be provided at a flow rate between about 0.5 sccm/L and about 5 sccm/L from the gas source 320, through the gas feed tube 345, and through the plurality of gas passages 311 in the showerhead 310, 410 into the processing region 306. Simultaneously, hydrogen radicals, generated in the remote plasma source 324 according to the description provided above with respect to FIG. 5, are provided through the line of sight tubing 347, the central feed tube 349, and the showerhead 310, 410 into the processing region 306. An RF power between about 300 mW/cm² or greater, preferably 600 mW/cm² or greater, may be provided to the showerhead 310, 410 to deliver energy to the silane and the hydrogen radical mixture in the processing region 306. The pressure of the processing chamber 300 may be between about 1 Torr and about 100 Torr, preferably between about 3 Tor and about 20 Torr.

Finally, while the substrate is still positioned in the processing chamber 300, an n-type amorphous silicon layer 126 is deposited over the intrinsic type microcrystalline silicon layer 124 on the substrate 201. In one embodiment, the n-type amorphous silicon layer 136 may be deposited by first depositing an optional first n-type amorphous silicon layer at a first silane flow rate and then depositing a second n-type amorphous silicon layer over the first optional n-type amorphous silicon layer at a second silane flow rate lower than the first silane flow rate. The first optional n-type amorphous silicon layer may be deposited by providing silane gas at a flow rate between about 1 sccm/L and about 10 sccm/L, such as about 5.5 sccm/L from the gas source 320, through the gas feed tube 345, and through the plurality of gas passages 311 in the showerhead 310, 410 into the processing region 306. Simultaneously, hydrogen radicals, generated in the remote plasma source 324 according to the description provided above with respect to FIG. 5, are provided through the line of sight tubing 347, the central feed tube 349, and the showerhead 310, 410 into the processing region 306. Phosphine may be provided at a flow rate between about 0.0005 sccm/L and about 0.0015 sccm/L, such as about 0.0095 sccm/L along with the silane. An RF power between about 25 mW/cm² and about 250 mW/cm² may be provided to the showerhead 310, 410 to deliver energy to the silane and the hydrogen radical mixture in the processing region 306. The pressure of the processing chamber 300 may be between about 0.1 Torr and about 20 Torr, preferably between about 0.5 Torr and about 4 Torr.

The second n-type amorphous silicon layer deposition may comprise providing silane gas at a flow rate between about 0.1 sccm/L and about 5 sccm/L, such as about 0.5 sccm/L and about 3 sccm/L, for example about 1.42 sccm/L from the gas source 320, through the gas feed tube 345, and through the plurality of gas passages 311 in the showerhead 310, 410 into the processing region 306. Simultaneously, hydrogen radicals, generated in the remote plasma source 324 according to the description provided above with respect to FIG. 5, are provided through the line of sight tubing 347, the central feed tube 349, and the showerhead 310, 410 into the processing region 306. Phosphine may be provided at a flow rate between about 0.01 sccm/L and about 0.075 sccm/L, such as between about 0.015 sccm/L and about 0.03 sccm/L, for example about 0.023 sccm/L. An RF power between about 25 mW/cm² and about 250 mW/cm², such as about 60 mW/cm² may be provided to the showerhead 310, 410 to deliver energy to the silane and the hydrogen radical mixture in the processing region 306. The pressure of the processing chamber 300 may be between about 0.1 Torr and about 20 Torr, such as between about 0.5 Torr and about 4 Torr, for example about 1.5 Torr.

Thus, each of the silicon-containing layers in a solar cell may be provided by generating hydrogen radicals in a remote plasma source and delivering the hydrogen radicals directly into the processing region of the processing chamber to combine with the silicon-containing gas according to embodiments of the present invention. Directly providing the hydrogen radicals into the processing region for reaction with the silicon-containing gas results in improved bonding structure, deposition efficiency, and deposited film stability over prior art deposition methods.

While the foregoing is directed to embodiments of the invention, other and further embodiments of the invention may be devised without departing from the basic scope thereof.

What is claimed is:

1. A method for depositing a silicon-containing film, comprising:
generating hydrogen radicals remotely from a processing chamber;
introducing a flow of the hydrogen radicals into a processing region of the processing chamber, wherein a substrate is positioned in the processing region; and
introducing a flow of silicon-containing gas into the processing region of the processing chamber, wherein the hydrogen radicals are not mixed with the silicon-containing gas prior to reaching the processing region of the processing chamber.

2. The method of claim 1, further comprising delivering a flow of argon plasma with the hydrogen radicals to the processing region.

3. The method of claim 1, wherein the hydrogen radicals are generated in a remote plasma source.

4. The method of claim 3, further comprising delivering the hydrogen radicals from the remote plasma source to the processing chamber via line of sight tubing comprising an inert material.

5. The method of claim 4, further comprising heating the line of sight tubing during the delivering the hydrogen radicals from the remote plasma source to the processing chamber.

6. The method of claim 4, wherein the processing region is defined by a substrate support, a showerhead, and walls of the processing chamber.

7. The method of claim 6, further comprising delivering the silicon-containing gas from a gas source to the processing region via a first plurality of gas passages disposed through the showerhead.

8. The method of claim 7, further comprising delivering the hydrogen radicals from the line of sight tubing into the processing region through a central opening in the showerhead.

9. The method of claim 7, further comprising delivering the hydrogen radicals from the line of sight tubing into the processing region through an interior region of the showerhead and a second plurality of gas passages in the showerhead coupling the interior region of the showerhead with the processing region of the processing chamber.

10. A method for depositing a silicon-containing film, comprising:
establishing a flow of argon gas into a remote plasma source;
igniting a plasma within the remote plasma source;
establishing a flow of hydrogen gas into the remote plasma source such that a flow of hydrogen radicals is established;
delivering the flow of hydrogen radicals into a processing region of a processing chamber, wherein a substrate is positioned in the processing region; and
generating a flow of silicon-containing gas into the processing region of the processing chamber, wherein the hydrogen radicals are not mixed with the silicon-containing gas prior to reaching the processing region of the processing chamber.

11. The method of claim 10, wherein the hydrogen gas flow is ramped up during the establishing a flow of hydrogen gas.

12. The method of claim 11, further comprising ramping down the flow of argon gas after establishing the flow of hydrogen gas.

13. The method of claim 12, further comprising delivering the hydrogen radicals from the remote plasma source to the processing region of the processing chamber via line of sight tubing comprising an inert material.

14. The method of claim 13, wherein the processing region is defined by a substrate support, a showerhead, and walls of the processing chamber.

15. The method of claim 14, further comprising delivering the silicon-containing gas from a gas source to the processing region via a first plurality of gas passages disposed through the showerhead.

16. The method of claim 15, further comprising delivering the hydrogen radicals from the line of sight tubing into the processing region through a central opening in the showerhead.

17. The method of claim 15, further comprising delivering the hydrogen radicals from the line of sight tubing into the processing region through an interior region of the showerhead and a second plurality of gas passages in the showerhead coupling the interior region of the showerhead with the processing region of the processing chamber.

18. An apparatus for depositing a silicon-containing film, comprising:
a processing chamber having a plurality of walls, a showerhead, and a substrate support that define a processing region within the processing chamber,
a silicon-containing gas source coupled to the processing region through a first plurality of gas passages disposed through the showerhead;
a remote plasma source coupled to a hydrogen gas source and configured to generate a plurality of hydrogen radicals therein;
tubing coupling the remote plasma source to the processing chamber, wherein the tubing comprises an inert material; and
a feed tube coupling the tubing to the processing region such that hydrogen radicals delivered by the feed tube do not mix with a silicon-containing gas prior to entering the processing region.

19. The apparatus of claim 18, wherein the showerhead has a central opening fluidly connected to the feed tube configured to introduce the hydrogen radicals directly into the processing region.

20. The apparatus of claim 18, wherein the showerhead has an interior region fluidly coupled to the feed tube configured to receive the hydrogen radicals and a second plurality of gas passages disposed in the showerhead and fluidly coupling the interior region of the showerhead with the processing region of the processing chamber.
